(19) United States
(12) Patent Application Publication
(10) Pub. No.: US 2025/0380473 A1
(43) Pub. Date: Dec. 11, 2025

(54) SEMICONDUCTOR DEVICE AND METHOD OF FABRICATING THE SAME

(71) Applicant: SAMSUNG ELECTRONICS CO., LTD., Suwon-si (KR)

(72) Inventors: Youngjin Yang, Suwon-si (KR); Byungho Moon, Suwon-si (KR); Kyoung-mi Park, Suwon-si (KR); Kyung Hee Cho, Suwon-si (KR); Namhyun Lee, Suwon-si (KR)

(21) Appl. No.: 19/009,723

(22) Filed: Jan. 3, 2025

(30) Foreign Application Priority Data
Jun. 5, 2024 (KR) 10-2024-0073635

(51) Int. Cl. H10D 62/10; H10D 30/00; H10D 30/01; H10D 30/43; H10D 62/13; H10D 62/17; H10D 64/27; H10D 84/01; H10D 84/83

(52) U.S. Cl. CPC H10D 62/115; H10D 30/014; H10D 30/0191; H10D 30/43; H10D 30/502; H10D 62/121; H10D 62/151; H10D 62/235; H10D 64/514; H10D 64/518; H10D 84/0128; H10D 84/0151; H10D 84/832

(57) ABSTRACT

A semiconductor device may include an active pattern on a substrate, a first channel pattern and a second channel pattern provided on the active pattern and spaced apart from each other, a separation pattern between the first and second channel patterns, the separation pattern including a body portion and a head portion on the body portion, a gate electrode on the first and second channel patterns, and an inner insulating pattern on a side surface of the body portion. The inner insulating pattern may include a first portion between the first channel pattern and the separation pattern and between the second channel pattern and the separation pattern and a second portion between the gate electrode and the separation pattern. A width of the first portion may be larger than a width of the second portion.

### CROSS-REFERENCE TO RELATED APPLICATION

This U.S. non-provisional patent application claims priority under 35 U.S.C. § 119 to Korean Patent Application No. 10-2024-0073635, filed on Jun. 5, 2024, in the Korean Intellectual Property Office, the entire contents of which are hereby incorporated by reference.

### BACKGROUND

A semiconductor device includes an integrated circuit including metal-oxide-semiconductor field-effect transistors (MOS-FETs). To meet an increasing demand for a semiconductor device with a small pattern size and a reduced design rule, the MOS-FETs are being aggressively scaled down. The scale-down of the MOS-FETs may lead to deterioration in operational properties of the semiconductor device. A variety of studies are being conducted to overcome technical limitations associated with the scale-down of the semiconductor device and to realize high-performance semiconductor devices.

### SUMMARY

Some aspects of the present disclosure provide semiconductor devices with improved electrical and reliability characteristics.

Some aspects of the present disclosure provide methods of fabricating semiconductor devices with improved electrical and reliability characteristics.

According to some aspects of the present disclosure, a semiconductor device may include an active pattern on a substrate, a first channel pattern and a second channel pattern provided on the active pattern and spaced apart from each other, a separation pattern between the first and second channel patterns, the separation pattern including a body portion and a head portion on the body portion, a gate electrode on the first and second channel patterns, and an inner insulating pattern on a side surface of the body portion. The inner insulating pattern may include a first portion between the first channel pattern and the separation pattern and between the second channel pattern and the separation pattern and a second portion between the gate electrode and the separation pattern. A width of the first portion may be larger than a width of the second portion.

According to some aspects of the present disclosure, a semiconductor device may include an active pattern on a substrate, a first channel pattern and a second channel pattern provided on the active pattern and spaced apart from each other in a first direction, a separation pattern between the first and second channel patterns, the separation pattern including a body portion and a head portion on the body portion, a gate electrode on the first and second channel patterns, and an inner insulating pattern covering opposite side surfaces of the body portion. The head portion may have a first width in the first direction, and the body portion may have a second width in the first direction. The inner insulating pattern may include a first sidewall and a second sidewall facing the gate electrode, and a distance between the first sidewall and the second sidewall in the first direction may be a third width. The third width may be larger than the second width and may be smaller than the first width.

According to some aspects of the present disclosure, a semiconductor device may include a substrate including an active pattern, a device isolation layer defining the active pattern, a first channel pattern and a second channel pattern provided on the active pattern and spaced apart from each other in a first direction, first source/drain patterns connected to the first and second channel patterns, a separation pattern between the first and second channel patterns, a gate electrode on the first and second channel patterns, a gate insulating layer interposed between the gate electrode and each of the first and second channel patterns, an inner insulating pattern on bottom and side surfaces of the separation pattern, a gate spacer on a side surface of the gate electrode, a gate capping pattern on a top surface of the gate electrode, an interlayer insulating layer covering the first and second source/drain patterns and the gate capping pattern, an active contact provided to penetrate the interlayer insulating layer and electrically connected to one of the first source/drain patterns, a gate contact provided to penetrate the gate capping pattern and the interlayer insulating layer and electrically connected to the gate electrode, and a first metal layer on the interlayer insulating layer. The first metal layer may include a first interconnection line electrically connected to the active contact and the gate contact. The separation pattern may include a body portion and a head portion on the body portion. The inner insulating pattern may include a first portion between the first channel pattern and the separation pattern and between the second channel pattern and the separation pattern and a second portion between the gate electrode and the separation pattern. A ratio of a width of the first portion to a width of the second portion may range from 1.5 to 5.

### BRIEF DESCRIPTION OF THE DRAWINGS

FIG. 1 is a plan view illustrating an example of a semiconductor device.

FIGS. 2A to 2C are sectional views taken along lines A-A′, B-B′, and C-C′ of FIG. 1, respectively.

FIG. 3A is an enlarged sectional view illustrating an example of a portion ‘P1’ of FIG. 2A.

FIG. 3B is an enlarged sectional view illustrating another example of the portion ‘P1’ of FIG. 2A.

FIGS. 4 to 14C are sectional views illustrating examples of methods of fabricating a semiconductor device.

### DETAILED DESCRIPTION

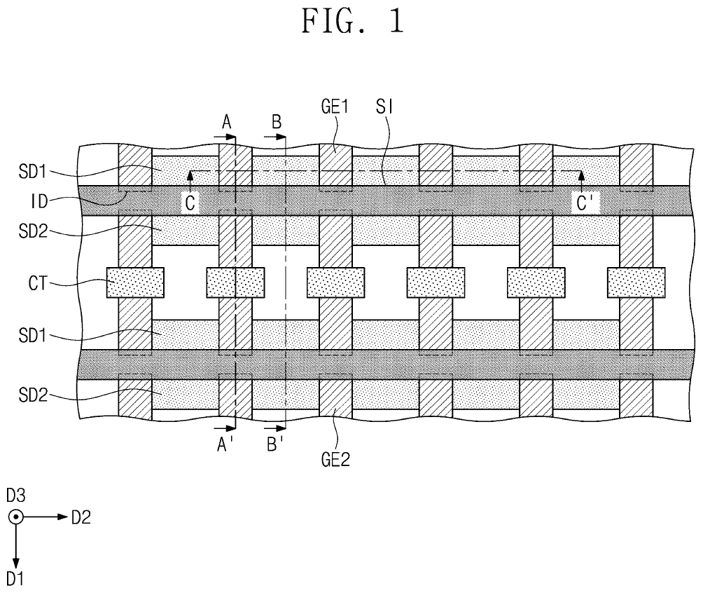

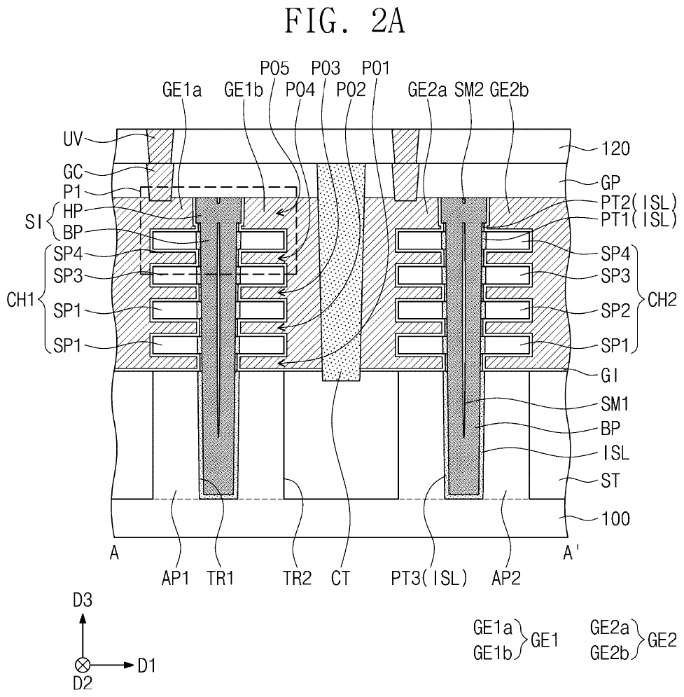

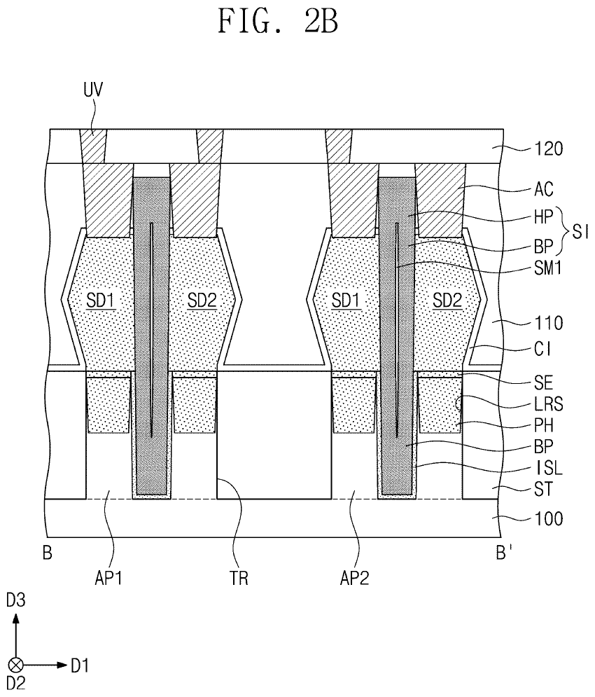

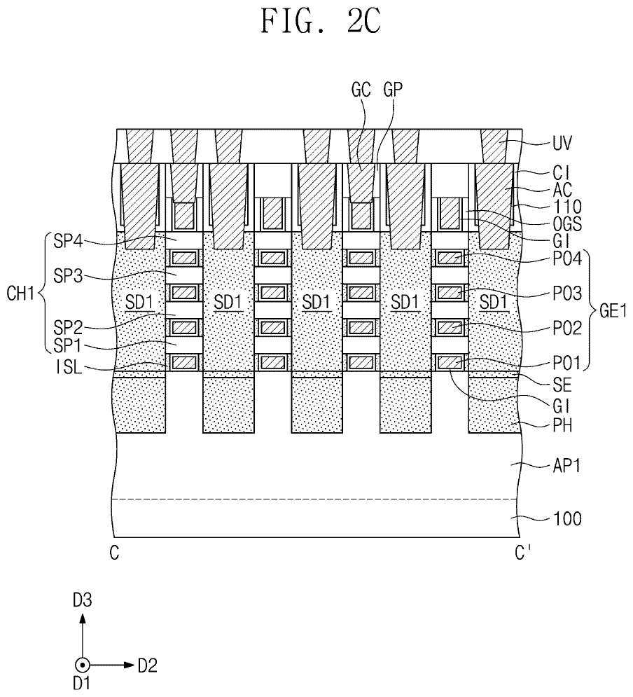

FIG. 1 is a plan view illustrating an example of a semiconductor device. FIGS. 2A to 2C are sectional views of the example of the semiconductor device, which are respectively taken along lines A-A′, B-B′, and C-C′ of FIG. 1.

Referring to FIG. 1 and FIGS. 2A to 2C, a semiconductor device may include a substrate 100. A plurality of logic transistors constituting a logic circuit may be disposed on the substrate 100. For example, the substrate 100 may be an insulating substrate including a silicon-based insulating layer. For example, the substrate 100 may be formed of or include at least one of, for example, silicon oxide, silicon nitride, or silicon oxynitride. In the present specification, each of the expressions of “A or B”, “at least one of A and B”, “at least one of A or B”, “A, B, or C”, “at least one of A, B, and C”, and “at least one of A, B, or C” may be used to represent one of the elements enumerated in the expression or any possible combination of the enumerated elements.

The substrate 100 may be a plate-shaped structure that is extended parallel to a plane defined by a first direction D1 and a second direction D2. The first and second directions D1 and D2 may be parallel to a top surface of the substrate 100 and may not be parallel to each other. For example, the first and second directions D1 and D2 may be orthogonal to each other.

First active patterns AP1 and second active patterns AP2 may be defined by first and second trenches TR1 and TR2 in the substrate 100. For example, each of the first or second active patterns AP1 or AP2 may be defined by the first trenches TR1, and the first and second active patterns AP1 and AP2 may be defined by the second trenches TR2. The first and second active patterns AP1 and AP2 may be a portion of the substrate 100. For example, the first and second active patterns AP1 and AP2 may be portions of the substrate 100 protruding in a third direction D3 perpendicular to the top surface of the substrate 100. However, for convenience in description, the substrate 100 and the first and second active patterns AP1 and AP2 will be described as if they are separate elements.

Each of the first and second active patterns AP1 and AP2 may extend in the second direction D2. The first active patterns AP1 and the second active patterns AP2 may be spaced apart from each other in the first direction D1 by a device isolation pattern ST to be described below. The first active patterns AP1 or the second active patterns AP2 may be spaced apart from each other in the first direction D1 by a separation pattern SI, which will be described below.

The device isolation pattern ST may be provided on the substrate 100. The device isolation pattern ST may fill the second trenches TR2. When viewed in a plan view, the device isolation pattern ST may enclose the first and second active patterns AP1 and AP2. A top surface of the device isolation pattern ST may be coplanar with top surfaces of the first and second active patterns AP1 and AP2, but the positioning is not limited to this example. The device isolation pattern ST may include, for example, an insulating material (e.g., silicon oxide).

A first channel pattern CH1 and a second channel pattern CH2 (e.g., as shown in FIGS. 2A and 2C) may be provided on the first and second active patterns AP1 and AP2, respectively. The first and second channel patterns CH1 and CH2 may be adjacent to each other in the first direction D1. The first and second channel patterns CH1 and CH2 may be spaced apart from each other in the first direction D1, with the separation pattern SI interposed therebetween. Each of the first and second channel patterns CH1 and CH2 may be provided in plural, and may be spaced apart from each other in the second direction D2.

Each of the first and second channel patterns CHI and CH2 may include a first semiconductor pattern SP1, a second semiconductor pattern SP2, a third semiconductor pattern SP3, and a fourth semiconductor pattern SP4. The first to fourth semiconductor patterns SP1, SP2, SP3, and SP4 may be spaced apart from each other in a vertical direction (e.g., the third direction D3). For example, the first to fourth semiconductor patterns SP1, SP2, SP3, and SP4 may include crystalline silicon. Each of the first to fourth semiconductor patterns SP1, SP2, SP3, and SP4 may be a nanosheet. It will be understood that the number of the semiconductor patterns in the first and second channel patterns CH1 and CH2 may be different from the four in this example.

First source/drain patterns SD1 and second source/drain patterns SD2 may be provided on each of the first and second active patterns AP1 and AP2. The first source/drain patterns SD1 may be placed on two opposite side surfaces of the first channel pattern CH1 and may be electrically connected to the first channel pattern CH1. The second source/drain patterns SD2 may be placed on two opposite side surfaces of the second channel pattern CH2 and may be electrically connected to the second channel pattern CH2. For example, the first source/drain patterns SD1 may be respectively placed between a plurality of first channel patterns CH1, and the second source/drain patterns SD2 may be respectively placed between a plurality of second channel patterns CH2.

The first and second source/drain patterns SD1 and SD2 may include impurity regions having a first conductivity type (e.g., p-type) or a second conductivity type (e.g., n-type). For example, the first and second source/drain patterns SD1 and SD2 may include impurity regions having the same conductivity type or having different conductivity types.

Seed patterns SE (shown, for example, in FIG. 2B) may be provided between the first and second source/drain patterns SD1 and SD2 and the first and second active patterns AP1 and AP2. Each of the first and second source/drain patterns SD1 and SD2 may be an epitaxial pattern, which is formed by a selective epitaxial growth (SEG) process using the seed patterns SE as a seed layer. For example, the first and second source/drain patterns SD1 and SD2 may be formed of or include at least one of silicon or silicon-germanium.

A first gate electrode GE1 may be provided on the first active patterns AP1, and a second gate electrode GE2 may be provided on the second active patterns AP2. The first gate electrode GE1 may be located on the first and second channel patterns CH1 and CH2 of the first active patterns AP1. The second gate electrode GE2 may be located on the first and second channel patterns CH1 and CH2 of the second active patterns AP2. For example, each of the first and second gate electrodes GE1 and GE2 may be provided to enclose each of the first to fourth semiconductor patterns SP1, SP2, SP3, and SP4 of the first and second channel patterns CH1 and CH2. The first and second gate electrodes GE1 and GE2 may be spaced apart from each other in the first direction D1 by cutting patterns CT, which will be described below.

In addition, each of the first and second gate electrodes GE1 and GE2 may include first to fourth inner electrodes PO1, PO2, PO3, and PO4 and an outer electrode PO5. Each of the first to fourth inner electrodes PO1, PO2, PO3, and PO4 may be positioned between the first semiconductor pattern SP1 and the first or second active patterns AP1 or AP2 and between the first to fourth semiconductor patterns SP1, SP2, SP3, and SP4. The outer electrode PO5 may be placed on the fourth semiconductor pattern SP4, which is the uppermost one of the first to fourth semiconductor patterns SP1, SP2, SP3, and SP4. For example, the first and second gate electrodes GE1 and GE2 may be formed of or include at least one of metallic materials (e.g., Ti, Mo, W, Cu, Al, Ta, Ru, Ir, and/or Co), metal nitride materials (e.g., containing Ti, Mo, W, Cu, Al, Ta, Ru, Ir, and/or Co), or doped poly silicon.

Separation patterns SI may be provided on the substrate 100. When viewed in a plan view, the separation patterns SI may extend in the second direction D2 and may be spaced apart from each other in the first direction D1. For example, the separation patterns SI may include an insulating material (e.g., silicon oxide, silicon nitride, silicon oxynitride, and silicon oxycarbide (SiOC)). In addition, the separation patterns SI may have a single-layered structure or may have a multi-layered structure including different insulating materials.

The separation pattern SI may be placed in the first trench TR1. The separation pattern SI may be provided to have a pillar shape extending in the third direction D3. The separation pattern SI may be placed between the first active patterns AP1 or the second active patterns AP2, which are adjacent to each other in the first direction D1. For example, the separation pattern SI may extend into or between the first active patterns AP1 or the second active patterns AP2, or portions thereof, which are adjacent to each other in the first direction D1. The separation pattern SI may be placed between the first and second channel patterns CH1 and CH2, which are adjacent to each other in the first direction D1.

The first gate electrode GE1 may include a first electrode portion GE1a and a second electrode portion GE1b. The first electrode portion GE1a may be located on the first channel pattern CH1, and the second electrode portion GE1b may be located on the second channel pattern CH2. For example, the first electrode portion GE1a may enclose three surfaces of each of the first to fourth semiconductor patterns SP1, SP2, SP3, and SP4 of the first channel pattern CH1, and the second electrode portion GE1b may enclose three surfaces of each of the first to fourth semiconductor patterns SP1, SP2, SP3, and SP4 of the second channel pattern CH2.

The first and second electrode portions GE1a and GE1b may be spaced apart from each other in the first direction D1 by the separation pattern SI. Thus, the first and second electrode portions GE1a and GE1b may be electrically disconnected from each other. Accordingly, the first and second channel patterns CH1 and CH2, which are adjacent to the separation pattern SI, may constitute logic transistors that are different from each other.

The separation pattern SI may include a body portion BP and a head portion HP on the body portion BP. The body portion BP may extend from the head portion HP toward a bottom surface of the substrate 100 in a vertical direction. A bottom surface of the body portion BP may be located at a level lower than the top surfaces of the first and second active patterns AP1 and AP2. The body portion BP may be extended into a space between the first and second channel patterns CH1 and CH2, which are adjacent to each other in the first direction D1, in the first trench TR1.

The body portion BP may be in contact with side surfaces of the first to fourth semiconductor patterns SP1, SP2, SP3, and SP4 of the first channel pattern CH1 and side surfaces of the first to fourth semiconductor patterns SP1, SP2, SP3, and SP4 of the second channel pattern CH2. The first and second gate electrodes GE1 and GE2, which are adjacent to the separation pattern SI, may enclose three surfaces of the first to fourth semiconductor patterns SP1, SP2, SP3, and SP4. The body portion BP may be located between the first and second source/drain patterns SD1 and SD2. Thus, the first and second source/drain patterns SD1 and SD2, which are adjacent to each other in the first direction D1, may be spaced apart from each other.

A gate insulating layer GI may be provided between the first and second gate electrodes GE1 and GE2 and the first to fourth semiconductor patterns SP1, SP2, SP3, and SP4 of the first and second channel patterns CH1 and CH2. The gate insulating layer GI may cover top, bottom, and side surfaces of each of the first to fourth semiconductor patterns SP1, SP2, SP3, and SP4. The gate insulating layer GI may cover opposite side surfaces and a bottom surface of the head portion HP of the separation pattern SI. The gate insulating layer GI may be interposed between an inner insulating pattern ISL and the first and second gate electrodes GE1 and GE2. The gate insulating layer GI may extend into a space between the first and second gate electrodes GE1 and GE2 and the device isolation pattern ST and between the first and second gate electrodes GE1 and GE2 and the first and second active patterns AP1 and AP2. The gate insulating layer GI may be placed between the outer electrode PO5 and outer gate spacers OGS to be described below.

The gate insulating layer GI may include at least one of silicon oxide, silicon oxynitride, and/or high-k dielectric materials. In the present specification, the high-k dielectric material may be a material having a dielectric constant higher than that of silicon oxide.

A pair of the outer gate spacers OGS (shown, for example, in FIG. 2C) may be provided on opposite side surfaces of the outer electrode PO5 of each of the first and second gate electrodes GE1 and GE2. The outer gate spacers OGS may be formed of or include at least one of, for example, SiON, SiCN, SiOCN, or SiN. In some implementations, the outer gate spacers OGS have a single-layered structure or have a multi-layered structure including different insulating materials.

Gate capping patterns GP may be provided on the first and second gate electrodes GE1 and GE2. The gate capping patterns GP may cover top surfaces of the outer electrodes PO5 of the first and second gate electrodes GE1 and GE2. The gate capping patterns GP may be formed of or include at least one of, for example, SiON, SiCN, SiOCN, or SiN.

A first interlayer insulating layer 110 may be provided on the substrate 100. The first interlayer insulating layer 110 may cover the first and second source/drain patterns SD1 and SD2. A top surface of the first interlayer insulating layer 110 may be substantially coplanar with top surfaces of the gate capping patterns GP. In some implementations, the first interlayer insulating layer 110 includes an insulating material (e.g., silicon oxide).

A capping insulating layer CI may be provided between the first interlayer insulating layer 110 and the first and second source/drain patterns SD1 and SD2. The capping insulating layer CI may be provided to cover the first and second source/drain patterns SD1 and SD2 and may be extended to a region on the device isolation pattern ST. In some implementations, the capping insulating layer CI includes an insulating material different from the first interlayer insulating layer 110. In some implementations, the capping insulating layer CI has a single-layered structure or has a multi-layered structure including different insulating materials.

Active contacts AC may be provided in the first interlayer insulating layer 110. The active contacts AC may penetrate or extend in a portion of the first interlayer insulating layer 110 in the third direction D3. The active contacts AC may be connected to the first and second source/drain patterns SD1 and SD2, respectively. For example, the active contacts AC may include at least one of metallic materials (e.g., Ti, Mo, W, Cu, Al, Ta, Ru, Ir, and/or Co) or metal nitride materials (e.g., containing Ti, Mo, W, Cu, Al, Ta, Ru, Ir, and/or Co). In some implementations, an additional separation pattern including an insulating material is provided between the active contacts AC. In some implementations, a silicide pattern is provided between the active contacts AC and the first and second source/drain patterns SD1 and SD2.

Gate contacts GC may be provided in the gate capping patterns GP. The gate contacts GC may penetrate or extend in the gate capping patterns GP in the third direction D3 and may be connected to the first and second gate electrodes GE1 and GE2. For example, the gate contacts GC may include at least one of metallic materials (e.g., Ti, Mo, W, Cu, Al, Ta, Ru, Ir, and Co) or metal nitride materials (e.g., containing Ti, Mo, W, Cu, Al, Ta, Ru, Ir, and Co).

Each of the cutting patterns CT may be provided between the first and second gate electrodes GE1 and GE2. The cutting patterns CT may extend in the third direction D3, between adjacent ones of the first and second gate electrodes GE1 and GE2. The cutting patterns CT may be provided to penetrate or extend in an upper portion of the device isolation pattern ST. For example, each of the cutting patterns CT may have a vertical length that is larger than a vertical length of each of the first and second gate electrodes GE1 and GE2. Thus, the first and second gate electrodes GE1 and GE2 may be spaced apart from each other in the first direction D1.

A second interlayer insulating layer 120 may be provided on the first interlayer insulating layer 110. The second interlayer insulating layer 120 may cover the first interlayer insulating layer 110, the gate capping patterns GP, the active contacts AC, and the gate contacts GC. The second interlayer insulating layer 120 may include substantially the same insulating material as the first interlayer insulating layer 110.

Upper vias UV may be provided in the second interlayer insulating layer 120. The upper vias UV may be provided to penetrate or extend in the second interlayer insulating layer 120. The upper vias UV may be connected to the active contacts AC and the gate contacts GC, respectively. For example, the upper vias UV may be formed of or include at least one of metallic materials (e.g., Ti, Mo, W, Cu, Al, Ta, Ru, Ir, and Co).

In some implementations, a metal layer including interconnection patterns and via patterns is provided on the upper vias UV. The interconnection patterns and the via patterns of the metal layer may be electrically connected to the upper vias UV. The metal layer may be used for signal exchange between adjacent ones of the logic transistors. In some implementations, a plurality of the metal layers are provided and may be stacked in the third direction D3.

In some implementations, a power delivery network layer is provided on the bottom surface of the substrate 100. For example, the power delivery network layer may include an interconnection network, which is used to apply a source voltage. As another example, the power delivery network layer may include an interconnection network, which is used to apply a drain voltage. In some implementations, the power delivery network layer includes interconnection patterns and via patterns. The interconnection patterns and the via patterns may be stacked in the third direction D3 and may be electrically connected to each other.

A back-side active contact may be provided between the power delivery network layer and the first and second source/drain patterns SD1 and SD2. The back-side active contact may be connected to at least one of the first and second source/drain patterns SD1 and SD2. The back-side active contact may be electrically connected to the interconnection patterns and the via patterns of the power delivery network layer. Thus, at least one of the first and second source/drain patterns SD1 and SD2 may be electrically connected to the power delivery network layer. For example, the back-side active contact may include at least one of metallic materials (e.g., Ti, Mo, W, Cu, Al, Ta, Ru, Ir, and/or Co) or metal nitride materials (e.g., containing Ti, Mo, W, Cu, Al, Ta, Ru, Ir, and/or Co).

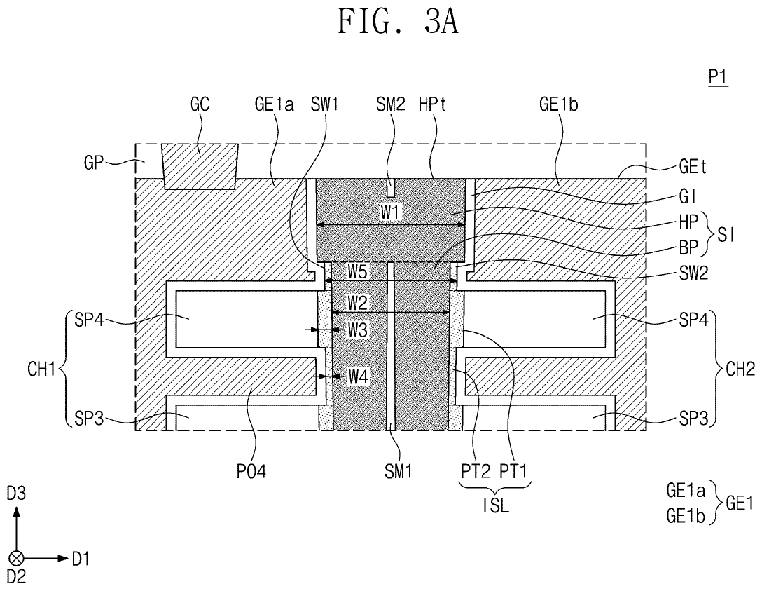

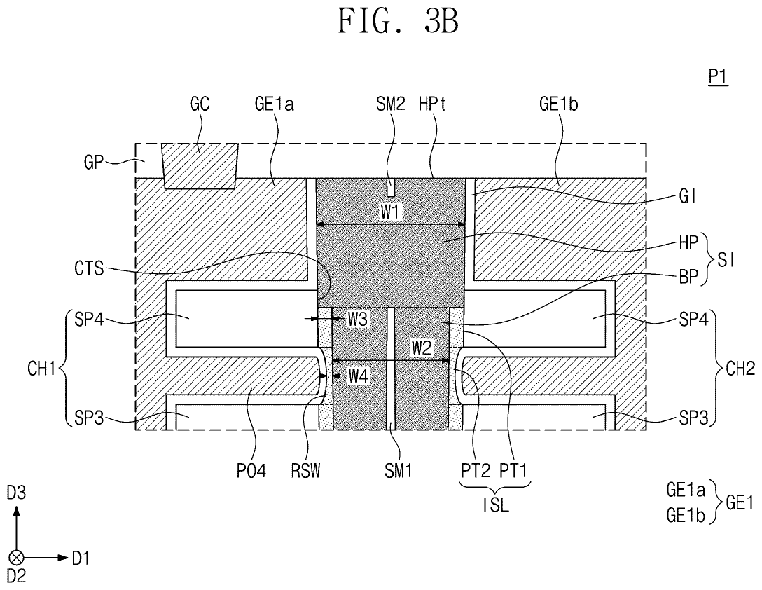

FIG. 3A is an enlarged sectional view illustrating an example of a portion ‘P1’ of FIG. 2A. The separation pattern SI will be described in more detail with reference to FIG. 3A.

Referring to FIGS. 2A and 3A, the head portion HP may be arranged on the body portion BP. A width of the head portion HP in the first direction D1 may be a first width W1. A width of the body portion BP in the first direction D1 may be a second width W2. The first width W1 may be larger than the second width W2. The first width W1 may be in a range from 5 nm to 30 nm. At an interface between the head and body portions HP and BP, the width of the separation pattern SI may be discontinuously changed. The head portion HP and the body portion BP may be formed of or include the same material and may form a single body. For example, the head and body portions HP and BP may include an insulating material (e.g., silicon nitride and silicon oxynitride). The head and body portions HP and BP may include different materials from each other. For example, the head portion HP may be formed of or include SiOCN, and the body portion BP may be formed of or include SiN.

The body portion BP may include a first seam SM1 therein. The first seam SM1 in the body portion BP may extend along the body portion BP and in the third direction D3. The first seam SM1 may be in contact with the head portion HP. The first seam SM1 may be sealed by the head portion HP.

The head portion HP may include a second seam SM2 in an upper portion thereof. The second seam SM2 may have a shape extending in the third direction D3. A length of the second seam SM2 in the third direction D3 may be shorter than that of the first seam SM1. The second seam SM2 may be in contact with the gate capping pattern GP. The second seam SM2 may be sealed by the gate capping pattern GP. The first seam SM1 and the second seam SM2 may be discontinuous from one another. In some implementations, the first and/or second seams SM1 and SM2 may not be formed.

The head portion HP may be located at a level higher than the fourth semiconductor patterns SP4 of the first and second channel patterns CH1 and CH2. For example, a bottom surface of the head portion HP may be located at a level higher than a top surface of the fourth semiconductor pattern SP4. The head portion HP may be spaced apart from the fourth semiconductor pattern SP4 in a vertical direction (i.e., the third direction D3). A top surface HPt of the head portion HP may be located at a level that is equal to or higher than a top surface GEt of the first and second gate electrodes GE1 and GE2.

The inner insulating pattern ISL may be provided to cover side and bottom surfaces of the body portion BP. The inner insulating pattern ISL may be provided between the first active patterns AP1 and the separation pattern SI and between the second active patterns AP2 and the separation pattern SI. The inner insulating pattern ISL may be provided between the separation pattern SI and the first and second gate electrodes GE1 and GE2. The inner insulating pattern ISL may be provided between the separation pattern SI and the first and second channel patterns CH1 and CH2.

The inner insulating pattern ISL may include a first portion PT1, which is interposed between (e.g., between in the first direction D1) the body portion BP and the first and second channel patterns CH1 and CH2, and a second portion PT2, which is provided between (e.g., between in the first direction D1) the body portion BP and the first and second gate electrodes GE1 and GE2. A width W3 of the first portion PT1 may be larger than a width W4 of the second portion PT2. A ratio of the width W3 of the first portion PT1 to the width W4 of the second portion PT2 may be in a range from 1.5 to 5. For example, the width W3 of the first portion PT1 may be in a range from 0.5 nm to 10 nm. The width W4 of the second portion PT2 may be in a range from 0.5 nm to 5 nm. Thus, the inner insulating pattern ISL may not have a constant thickness.

In some implementations, in association with the width W3 of the first portion PT1 being larger than the width W4 of the second portion PT2, a length of each of the first to fourth inner electrodes PO1, PO2, PO3, and PO4 in the first direction D1 may be larger than a length of each of the first to fourth semiconductor patterns SP1, SP2, SP3, and SP4 in the first direction D1. Based on this arrangement, it may be possible to increase a vertical overlapping length of the first to fourth semiconductor patterns SP1, SP2, SP3, and SP4 and the inner electrodes PO1, PO2, PO3, and PO4. For example, as shown in FIG. 3A, a contact length between the fourth semiconductor pattern SP4 and the fourth inner electrode PO4 may be increased.

The first and second portions PT1 and PT2 may include the same material. For example, the first and second portions PT1 and PT2 may include an insulating material (e.g., silicon oxide). In some implementations, the first and second portions PT1 and PT2 include different materials from each other. The first portion PT1 may include a material having an etch selectivity with respect to the second portion PT2.

A top surface of the inner insulating pattern ISL may be located at a level higher than a top surface of the fourth semiconductor pattern SP4 of the first and second channel patterns CH1 and CH2. The top surface of the inner insulating pattern ISL may be in direct contact with the head portion HP. The second portion PT2 of the inner insulating pattern ISL may be in direct contact with the head portion HP.

The inner insulating pattern ISL may include a first sidewall SW1 and a second sidewall SW2, which are provided in an upper portion thereof and face the first gate electrode GE1. For example, the first sidewall SW1 may face the first electrode portion GE1a of the first gate electrode GE1. The second sidewall SW2 may face the second electrode portion GE1b of the first gate electrode GE1. The first and second sidewalls SW1 and SW2 may face the outer electrode PO5. The first and second sidewalls SW1 and SW2 may be opposite to each other in the first direction D1. The first and second sidewalls SW1 and SW2 may be located at a level higher than the fourth semiconductor pattern SP4.

A distance between the first and second sidewalls SW1 and SW2 in the first direction D1 may be a fifth width W5. The fifth width W5 may be smaller than the first width W1 and may be larger than the second width W2. For example, the fifth width W5 may be smaller than a width of the head portion HP and may be larger than a width of the body portion BP. A side surface of the head portion HP facing the first electrode portion GE1a of the first gate electrode GE1 may protrude in the first direction D1 than the fist side wall SW1. An opposite side surface of the head portion HP facing the second electrode portion GE1b of the first gate electrode GE1 may protrude in the first direction D1 than the second sidewall SW2.

Referring back to FIG. 2A, the inner insulating pattern ISL may include a third portion PT3 between the body portion BP and the first and second active patterns AP1 and AP2. A width of the third portion PT3 may be larger than a fourth width W4 of the second portion PT2. For example, the width of the third portion PT3 may be in a range from 0.5 nm to 10 nm. The third portion PT3 may include a material different from the second portion PT2. The third portion PT3 may include the same material as the first portion PT1.

According to some implementations of the present disclosure, the first portion PT1 of the inner insulating pattern ISL may be wider than the second portion PT2. Thus, it may be possible to increase the length of the first to fourth semiconductor patterns SP1, SP1, SP3, and SP4, which are vertically overlapping with the first to fourth inner electrodes PO1, PO2, PO3, and PO4, without reducing the horizontal length of the first to fourth inner electrodes PO1, PO2, PO3, and PO4. In addition, the first and second channel patterns CH1 and CH2 may be spaced apart from the separation pattern SI by the inner insulating pattern ISL, and thus, it may be possible to prevent the performance of the semiconductor device from being deteriorated by a parasitic capacitance and fixed charges between the separation pattern SI and the first and second channel patterns CH1 and CH2.

In some implementations, since the separation pattern SI includes the head portion HP having a larger width than the body portion BP, it may be possible to prevent the first seam SM1 of the body portion BP from being exposed to the outside. In some implementations, a width of the head portion HP may be larger than a sum of a width of the body portion BP and a width of the inner insulating pattern ISL, which covers opposite side surfaces of the body portion BP. Accordingly, it may be possible to prevent the body portion BP and the inner insulating pattern ISL from being damaged or removed in the fabrication process. As a result, the reliability and electrical characteristics of the semiconductor device may be improved.

FIG. 3B is an enlarged sectional view illustrating another example of the portion ‘P1’ of FIG. 2A. For concise description, an element of a semiconductor device, which was previously described with reference to FIG. 3A, may be identified by a similar or identical reference number without repeating an overlapping description thereof. The descriptions provided with respect to elements of FIGS. 2A-2C and 3A apply equally to corresponding elements of FIG. 3B, except where noted otherwise or suggested otherwise by context.

Referring to FIG. 3B, the head portion HP may be in contact with portions of the fourth semiconductor patterns SP4 of the first and second channel patterns CH1 and CH2. For example, a sidewall CTS of the head portion HP may be in contact with side surfaces of the fourth semiconductor patterns SP4. For example, the head portion HP may be placed between the uppermost ones of the semiconductor patterns of the first and second channel patterns CH1 and CH2 and may be in contact with the uppermost ones of the semiconductor patterns. The first portion PT1 of the inner insulating pattern ISL may be in direct contact with the head portion HP.

The second portion PT2 of the inner insulating pattern ISL may include a recessed sidewall RSW. The recessed sidewall RSW of the second portion PT2 may face the first to fourth inner electrodes PO1, PO2, PO3, and PO4. The recessed sidewall RSW may have a shape that is recessed from the first to fourth inner electrodes PO1, PO2, PO3, and PO4 toward the second portion PT2. The recessed sidewall RSW may be a sidewall that is concavely recessed toward a center portion of the second portion PT2. Due to the recessed sidewall RSW, the fourth width W4 of the second portion PT2 may not be uniform. For example, the fourth width W4 may decrease as the height is lowered from a top portion of the second portion PT2 to the center portion, may reach a minimum value at the center portion, and may increase as the height is lowered from the center portion to a bottom portion.

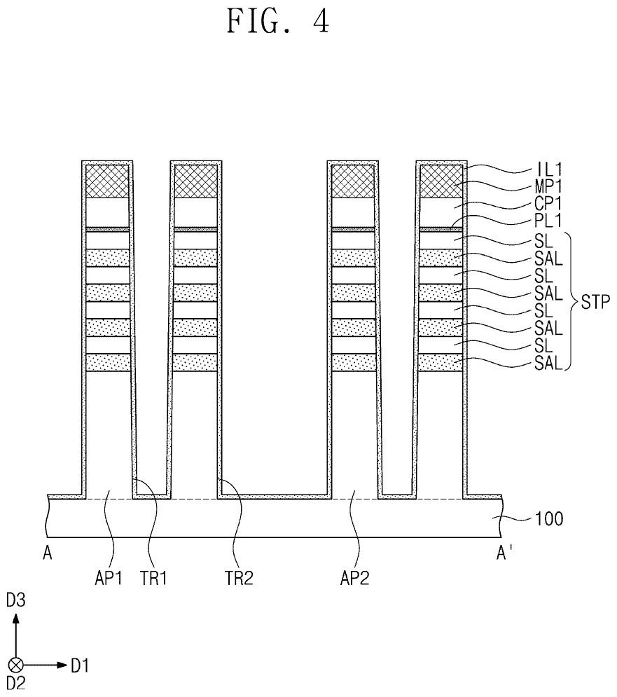

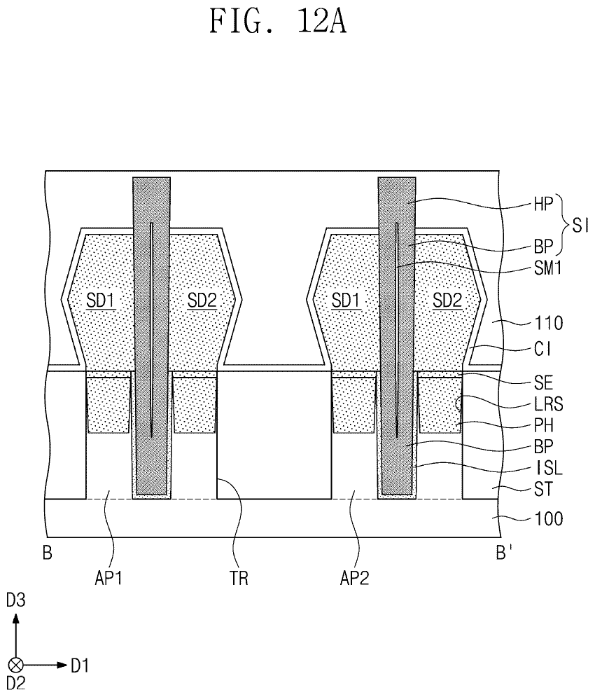

FIGS. 4 to 14C are sectional views illustrating an example of a method of fabricating a semiconductor device. In detail, FIGS. 4, 5, 6, 7, 8A, 8B, 9, 13, and 14A are sectional views taken along the line A-A′ of FIG. 1. FIGS. 10A, 11A, 12A, and 14B are sectional views taken along the line B-B′ of FIG. 1. FIGS. 10B, 11B, 12B, and 14C are sectional views taken along the line C-C′ of FIG. 1. The method of FIGS. 4 to 14C can be used, for example, to fabricate the semiconductor devices described with respect to FIGS. 1, 2A to 2C, 3A, and 3B.

Referring to FIG. 4, the substrate 100 may be provided. For example, the substrate 100 may be a semiconductor substrate that is formed of or includes silicon, germanium, silicon germanium, or a compound semiconductor material.

Stacking patterns STP, a first protection layer PL1, and a first capping pattern CP1 may be sequentially formed on the substrate 100. The stacking patterns STP may include semiconductor layers SL and sacrificial layers SAL, which are alternately stacked in the third direction D3. The sacrificial layers SAL may include a material having an etch selectivity with respect to the semiconductor layers SL. The semiconductor layers SL may be slightly removed or hardly removed in a process of removing the sacrificial layers SAL to be described below. For example, the semiconductor layers SL and the sacrificial layers SAL may be formed of or include at least one of silicon, germanium, and silicon-germanium and may be formed of different materials from each other. The first protection layer PL1 may include an insulating material. The first capping pattern CP1 may include silicon-germanium.

A first mask pattern MP1 may be formed on the first capping pattern CP1. The first mask pattern MP1 may include a material having an etch selectivity with respect to the first capping pattern CP1. For example, the first mask pattern MP1 may include silicon nitride.

The formation of the stacking patterns STP, the first protection layer PL1, and the first capping pattern CP1 may include alternatingly forming the semiconductor layers SL and the sacrificial layers SAL on the substrate 100, forming the first protection layer PL1 and the first capping pattern CP1, and performing a patterning process using the first mask pattern MP1 as a mask. In some implementations, an upper portion of the substrate 100 is etched by the patterning process. Thus, the first and second trenches TR1 and TR2 defining the first and second active patterns AP1 and AP2 may be formed. Each of the first and second active patterns AP1 and AP2 may be extended in the second direction D2.

A first insulating layer IL1 may be conformally formed on the substrate 100. The first insulating layer IL1 may cover side surfaces of the stacking patterns STP, the first protection layer PL1, the first capping pattern CP1, and the first mask pattern MP1. The first insulating layer IL1 may cover an inner surface of each of the first and second trenches TR1 and TR2. The first insulating layer IL1 may be formed to have a constant thickness. The first insulating layer IL1 may include an insulating material (e.g., silicon oxide).

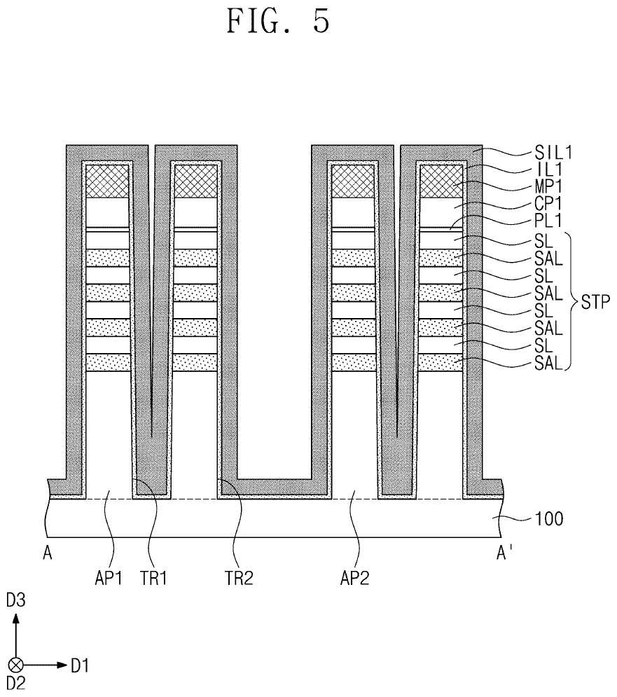

Referring to FIG. 5, a first separation pattern layer SIL1 may be conformally formed on the first insulating layer IL1. The first separation pattern layer SIL1 may fill the first trenches TR1. The first separation pattern layer SIL1 may be formed to have a constant thickness, and the thickness of the first separation pattern layer SIL1 may be larger than the thickness of the first insulating layer IL1. The first separation pattern layer SIL1 may include a material having an etch selectivity with respect to the first insulating layer IL1. The first separation pattern layer SIL1 may be formed of or include at least one of, for example, insulating materials (e.g., silicon oxide, silicon nitride, silicon oxynitride, and silicon oxycarbide (SiOC)).

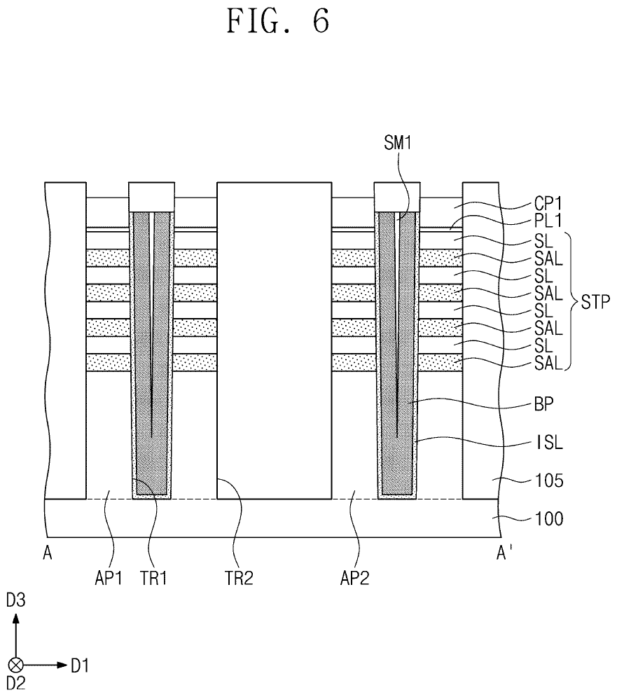

Referring to FIG. 6, the inner insulating pattern ISL and the body portion BP of the separation pattern SI may be formed in the first trenches TR1. The formation of the inner insulating pattern ISL and the body portion BP may include performing an etch-back process on the substrate 100 to partially remove the first insulating layer IL1 and the first separation pattern layer SIL1. Here, the first insulating layer IL1 and the first separation pattern layer SIL1 may be removed from the second trenches TR2, but the first insulating layer IL1 and the first separation pattern layer SIL1 in the first trenches TR1 may not be removed. In this case, a remaining portion of the first insulating layer IL1 may be used as the inner insulating pattern ISL, and a remaining portion of the first separation pattern layer SIL1 may be used as the body portion BP.

Due to a high aspect ratio of the first trenches TR1, the first seam SM1 may be formed in the body portion BP. The first seam SM1 in the body portion BP may have a shape extending in the third direction D3. A top surface of the body portion BP may be higher than a top surface of the uppermost semiconductor layer SL. The top surface of the body portion BP may be higher than a top surface of the first protection layer PL1.

A device isolation layer 105 may be formed in the second trenches TR2. The device isolation layer 105 may fill the second trenches TR2. Since the second trenches TR2 have a smaller aspect ratio than the first trenches TR1, a seam or void may not be formed in the device isolation layer 105. A top surface of the device isolation layer 105 may be located at a level higher than a top surface of the first capping pattern CP1. The device isolation layer 105 may be formed on the body portion BP. The first seam SM1 may not be exposed to the outside by the device isolation layer 105, e.g., may be entirely covered by the device isolation layer 105 so as to not be exposed outside the device.

The formation of the device isolation layer 105 may include forming an insulating material on the substrate 100, performing a planarization process on the insulating material to expose the first mask pattern MP1, and removing the first mask pattern MP1 to expose the first capping pattern CP1.

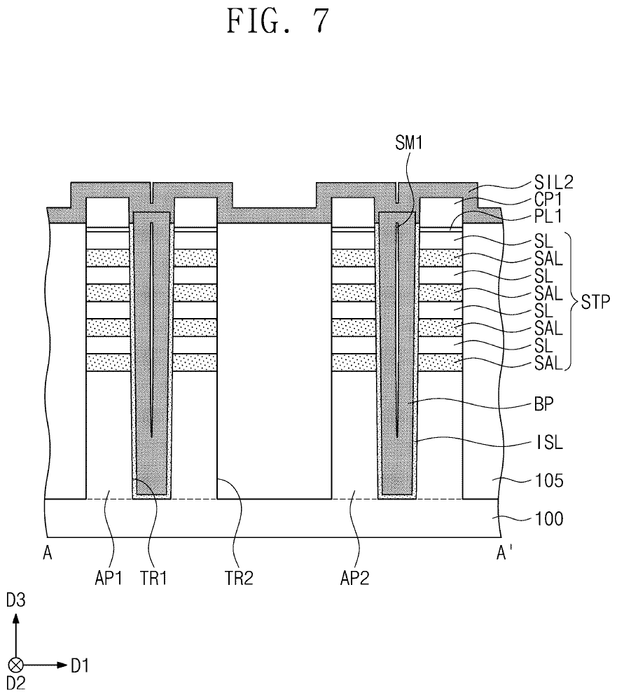

Referring to FIG. 7, an upper portion of the device isolation layer 105 may be etched, and thus, the height of the device isolation layer 105 may be reduced. As a result of the etching of the device isolation layer 105, the body portion BP may be exposed. The top surface of the device isolation layer 105 may be located at a level lower than the top surface of the first capping pattern CP1.

A second separation pattern layer SIL2 may be conformally formed on the substrate 100. The second separation pattern layer SIL2 may cover the top surface of the first capping pattern CP1. The second separation pattern layer SIL2 may cover a top surface and opposite side surfaces of the first capping pattern CP1. The first seam SM1 of the body portion BP may be sealed by the second separation pattern layer SIL2. The second separation pattern layer SIL2 may include the same material as the first separation pattern layer SIL1. The second separation pattern layer SIL2 may include a material different from the first separation pattern layer SIL1. For example, the second separation pattern layer SIL2 may be formed of or include SiOCN, and the first separation pattern layer SIL1 may be formed of or include SiN.

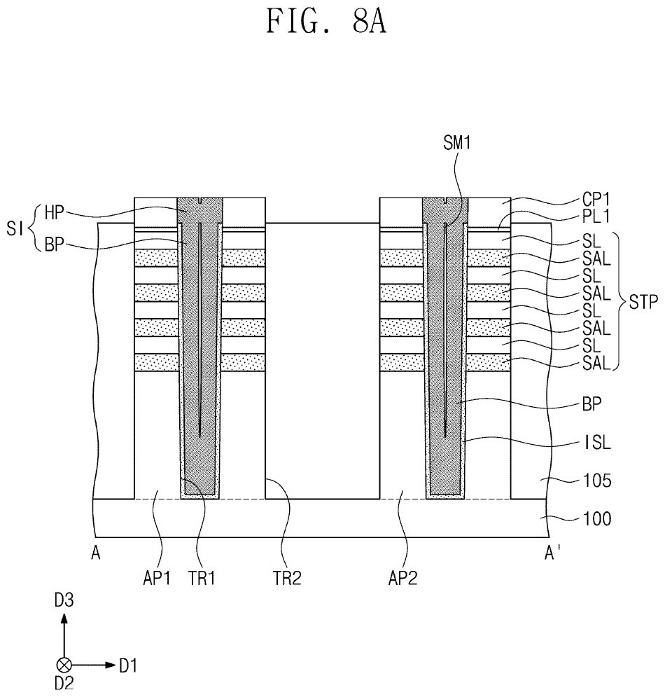

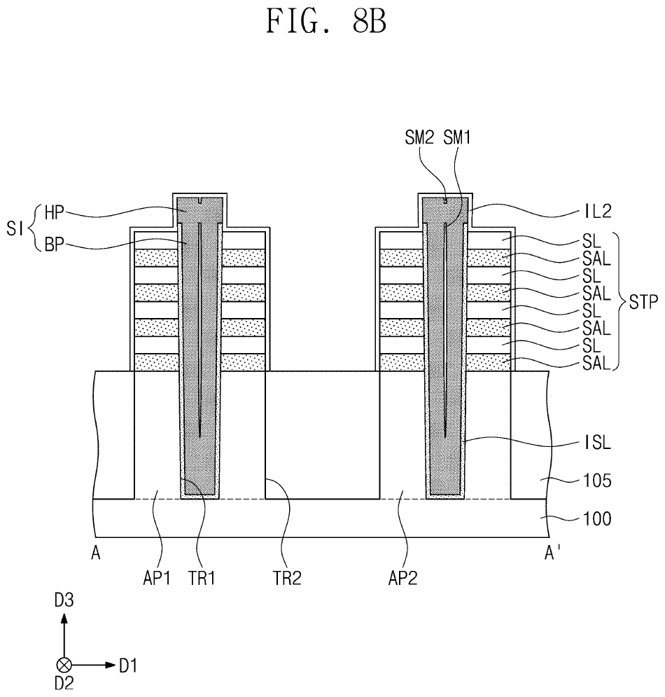

Referring to FIG. 8A, the head portion HP of the separation pattern SI may be formed by performing an etch-back process on the second separation pattern layer SIL2. Due to the high aspect ratio of the first trenches TR1, the second seam SM2 may be formed in an upper portion of the head portion HP. A height of a top surface of the head portion HP may be equal to or higher than a height of a top surface of the first capping pattern CP1.

The head portion HP may have a horizontal size that is larger than the body portion BP. An upper portion of the body portion BP may not be exposed to the outside by the head portion HP, e.g., may be entirely covered by the head portion HP. The inner insulating pattern ISL covering the opposite side surfaces of the body portion BP may not be exposed to the outside by the head portion HP. Thus, the head portion HP may prevent the body portion BP and the inner insulating pattern ISL from being unintentionally removed or damaged in a subsequent fabrication process. That is, the head portion HP may protect the body portion BP. Accordingly, when gate electrodes will be formed in a subsequent step to be spaced apart from each other with the separation pattern SI interposed therebetween, it may be possible to achieve a sufficient distance between the gate electrodes, e.g., without removing or damaging the body portion BP. Thus, the durability and electrical characteristics of the semiconductor device may be improved.

FIG. 8B illustrates another example of the fabrication process performed as an alternative to FIG. 8A. In the following description of FIG. 8B, the focus will be on features that differ from the example of FIG. 8A, in order to minimize overlapping descriptions.

Referring to FIG. 8B, the first capping pattern CP1 and the first protection layer PL1 may be removed. The removal of the first capping pattern CP1 may be performed to adjust a height of the head portion HP. For example, by etching a lower portion of the head portion HP while removing the first capping pattern CP1, it may be possible to adjust a vertical length of the head portion HP.

A second insulating layer IL2 may be conformally formed on the substrate 100. The second insulating layer IL2 may cover a top surface and opposite side surfaces of each of the head portion HP and the stacking patterns STP. The second insulating layer IL2 may include an insulating material (e.g., silicon oxide).

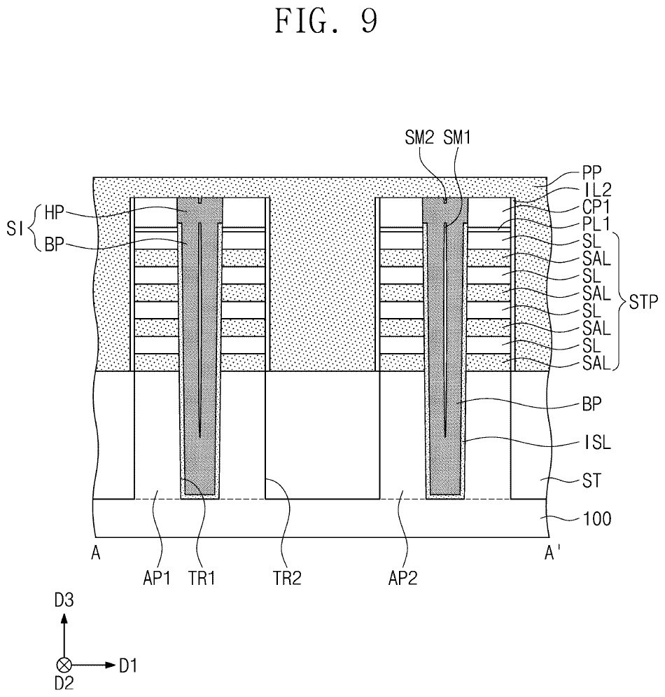

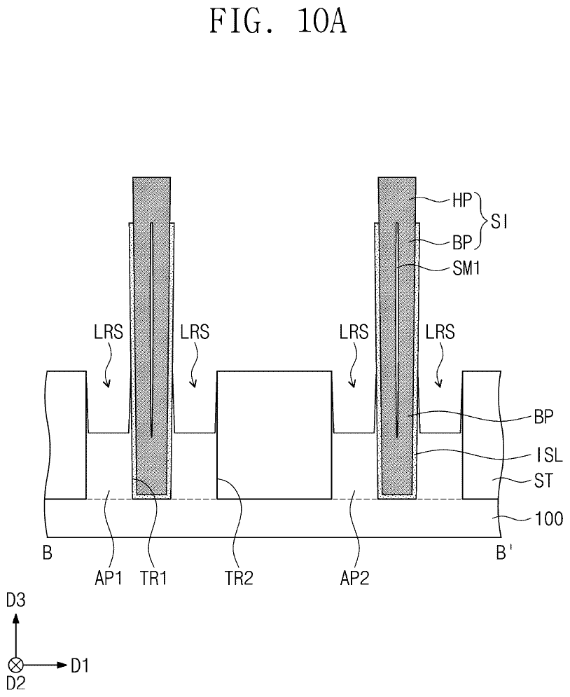

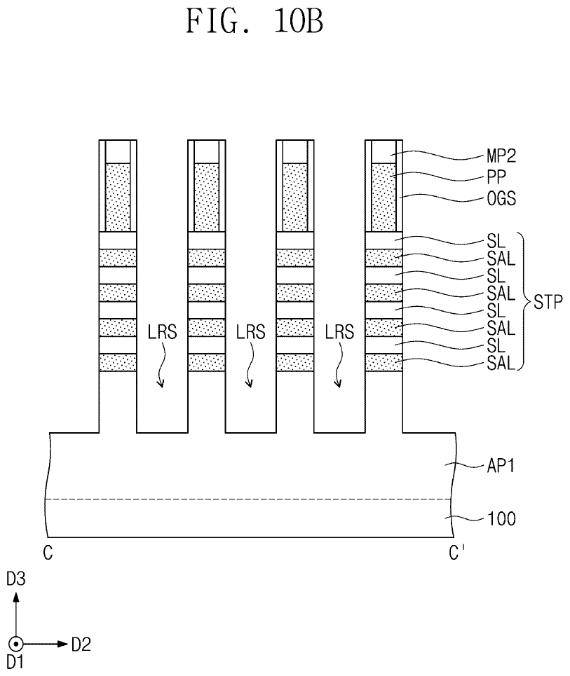

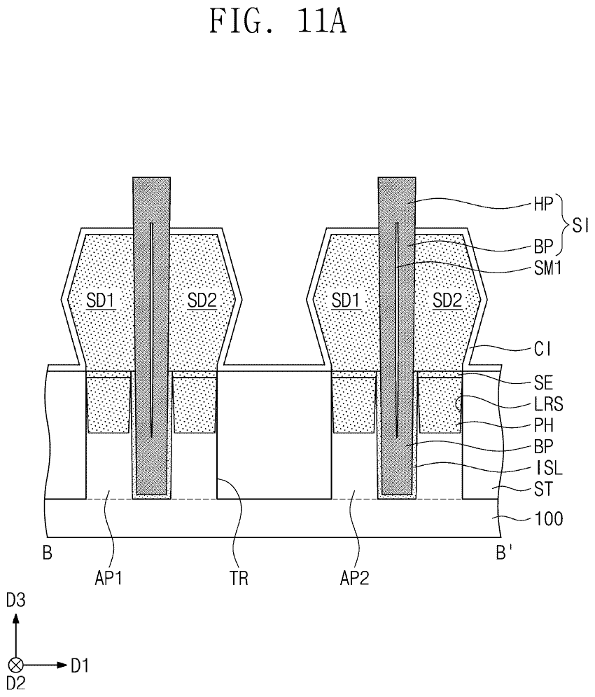

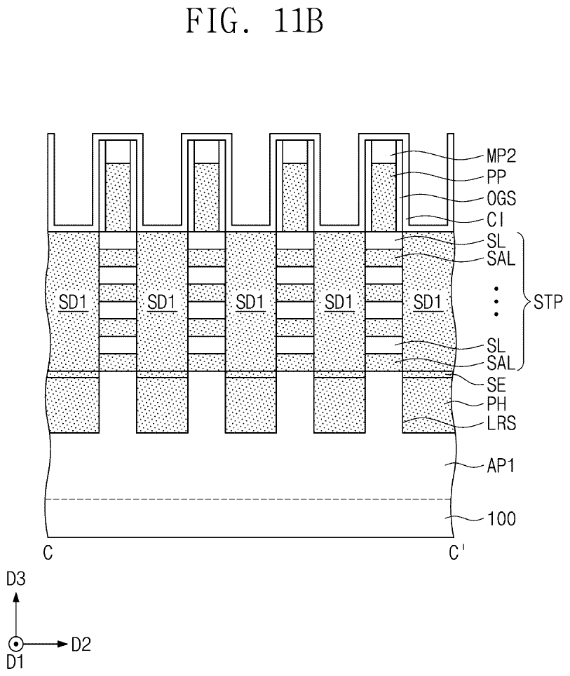

Referring to FIG. 9, a portion of the device isolation layer 105 may be removed until the top surface of the device isolation layer 105 is substantially coplanar with top surfaces of the first and second active patterns AP1 and AP2. Thus, the device isolation pattern ST may be formed from the device isolation layer 105. The top surface of the device isolation pattern ST may be located at a level that is equal to, or lower than, the top surfaces of the first and second active patterns AP1 and AP2. The second insulating layer IL2 may be formed to cover side surfaces of the stacking patterns STP and the first capping pattern CP1. The second insulating layer IL2 may be substantially the same as the second separation pattern layer SIL2 of FIG. 8B.

Next, a plurality of sacrificial patterns PP may be formed on the stacking patterns STP to cross the stacking patterns STP. Each of the sacrificial patterns PP may be formed in a line shape extending in the first direction D1. The formation of the sacrificial patterns PP may include forming a sacrificial layer on the substrate 100, forming second mask patterns on the sacrificial layer, and patterning the sacrificial layer using the second mask patterns. The sacrificial layer may include, for example, amorphous silicon and/or polysilicon.

Referring to FIGS. 10A and 10B, a pair of the outer gate spacers OGS may be formed on opposite side surfaces of the sacrificial patterns PP. The formation of the outer gate spacers OGS may include forming a spacer layer to cover the sacrificial patterns PP and the second mask patterns and isotropically etching the spacer layer. For example, the spacer layer may have a single layer or may have a multi-layered structure including two or more different insulating materials.

Thereafter, an etching process may be performed using the outer gate spacers OGS and the second mask patterns. The etching process may be performed to partially remove the stacking patterns STP and the first and second active patterns AP1 and AP2. As a result of the etching process, lower recesses LRS may be formed between the sacrificial patterns PP, which are adjacent to each other in the second direction D2. Owing to the lower recesses LRS, the stacking patterns STP may have a shape extending in the third direction D3.

The head portion HP of the separation pattern SI, which is not covered with the sacrificial patterns PP, may be partially removed by the etching process using the outer gate spacers OGS and the second mask patterns. For example, a portion of the head portion HP may be left on the body portion BP of the separation pattern SI. A head portion HP may be newly formed on the body portion BP. The head portion HP of FIG. 10A may be higher than a height of the head portion HP of FIG. 9. The head portion HP of FIG. 10A may be used to seal the first seam SM1 of the body portion BP. The head portion HP of FIG. 10A may not include a seam or void.

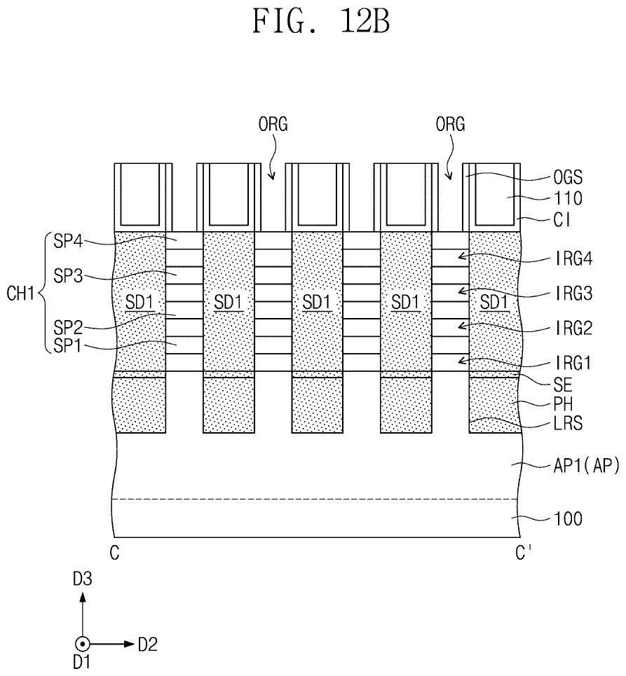

Referring to FIGS. 11A and 11B, sacrificial contact patterns PH may be formed in the first and second active patterns AP1 and AP2 exposed by the lower recesses LRS. The sacrificial contact patterns PH may be formed in a contact shape. The sacrificial contact patterns PH may include a material having an etch selectivity with respect to the first and second active patterns AP1 and AP2. For example, the sacrificial contact patterns PH may be formed by an epitaxial growth process and may include silicon-germanium.

The seed patterns SE and the first and second source/drain patterns SD1 and SD2 may be sequentially formed on each of the sacrificial contact patterns PH. The first and second source/drain patterns SD1 and SD2 may be formed by a selective epitaxial growth process using the seed patterns SE as a seed layer. During the formation of the first and second source/drain patterns SD1 and SD2, impurities may be injected into the first and second source/drain patterns SD1 and SD2 in an in-situ manner. As another example, impurities may be injected into the first and second source/drain patterns SD1 and SD2, after the formation of the first and second source/drain patterns SD1 and SD2.

Since, in the operations of FIGS. 10A and 10B, the stacking patterns STP, which are not covered with the sacrificial patterns PP, are etched, a portion of the inner insulating pattern ISL may be removed before the formation of the first and second source/drain patterns SD1 and SD2. Thus, the inner insulating pattern ISL may be absent between the body portion BP of the separation pattern SI and the first and second source/drain patterns SD1 and SD2. Accordingly, the body portion BP of the separation pattern SI may be in direct contact with the first and second source/drain patterns SD1 and SD2. A top surface of the head portion HP of the separation pattern SI may be higher than top surfaces of the first and second source/drain patterns SD1 and SD2.

Next, the capping insulating layer CI may be formed on the substrate 100. The capping insulating layer CI may cover the second mask patterns MP2, the first and second source/drain patterns SD1 and SD2, and the device isolation pattern ST with a constant thickness.

Referring to FIGS. 12A and 12B, the first interlayer insulating layer 110 may be formed on the first and second source/drain patterns SD1 and SD2. The first interlayer insulating layer 110 may cover the capping insulating layer CI. Next, a planarization process may be performed on the first interlayer insulating layer 110 to expose top surfaces of the sacrificial patterns PP. The second mask patterns MP2 on the sacrificial patterns PP may also be removed during the planarization process. Accordingly, the top surface of the first interlayer insulating layer 110 may be coplanar with the top surfaces of the sacrificial patterns PP and the top surfaces of the outer gate spacers OGS.

The exposed sacrificial patterns PP may be selectively removed. The removal of the sacrificial patterns PP may include a wet etching process, which is performed using an etching solution capable of selectively removing polysilicon. Since the sacrificial patterns PP are removed, an outer region ORG may be formed. Owing to the outer region ORG, the stacking patterns STP may be exposed to the outside.

The sacrificial layers SAL of the stacking patterns STP, which are exposed through the outer region ORG, may be selectively removed. An inner region IRG may be formed as a result of the selective removal of the sacrificial layers SAL. An etching process of selectively removing the sacrificial layers SAL may be performed to leave the semiconductor layers SL and to remove only the sacrificial layers SAL. The etching process of removing the sacrificial layers SAL may be performed using an etch recipe that is chosen to have a high etch rate to silicon germanium. Accordingly, channel patterns of a logic transistor may be formed from the semiconductor layers SL. For example, the first and second channel patterns CH1 and CH2 including the first to fourth semiconductor patterns SP1, SP2, SP3, and SP4 may be formed.

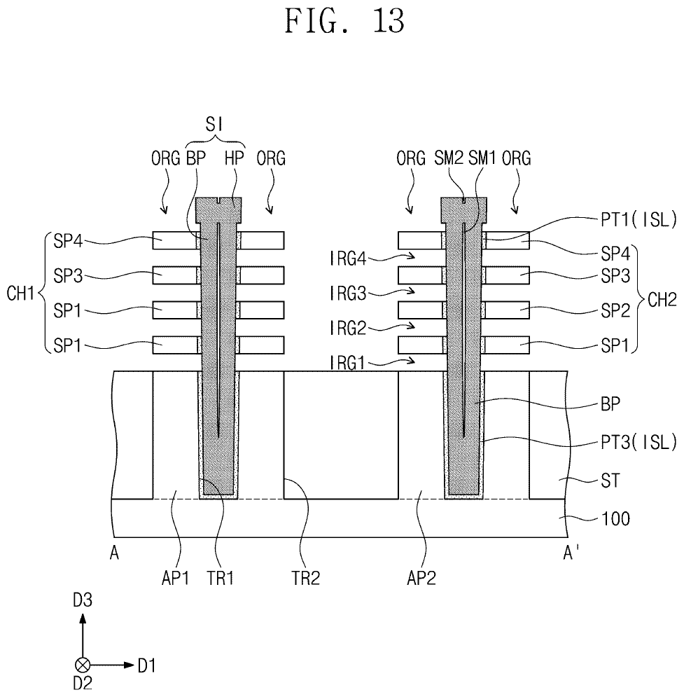

Referring to FIG. 13, the inner insulating pattern ISL on a side surface of the body portion BP of the separation pattern SI may be exposed through the first to fourth inner regions IRG1, IRG2, IRG3, and IRG4. A portion of the inner insulating pattern ISL, which is exposed by the first to fourth inner regions IRG1, IRG2, IRG3, and IRG4, may be selectively removed. Meanwhile, the inner insulating pattern ISL between the first and second active patterns AP1 and AP2 and the body portion BP may be left to form the third portion PT3 of the inner insulating pattern ISL. The inner insulating pattern ISL between the first and second channel patterns CH1 and CH2 and the body portion BP may be left to form the first portion PT1 of the inner insulating pattern ISL. Since the inner insulating pattern ISL includes a material having an etch selectivity with respect to the body portion BP, the body portion BP may not be etched. In some implementations, the first portion PT1 is partially or fully removed.

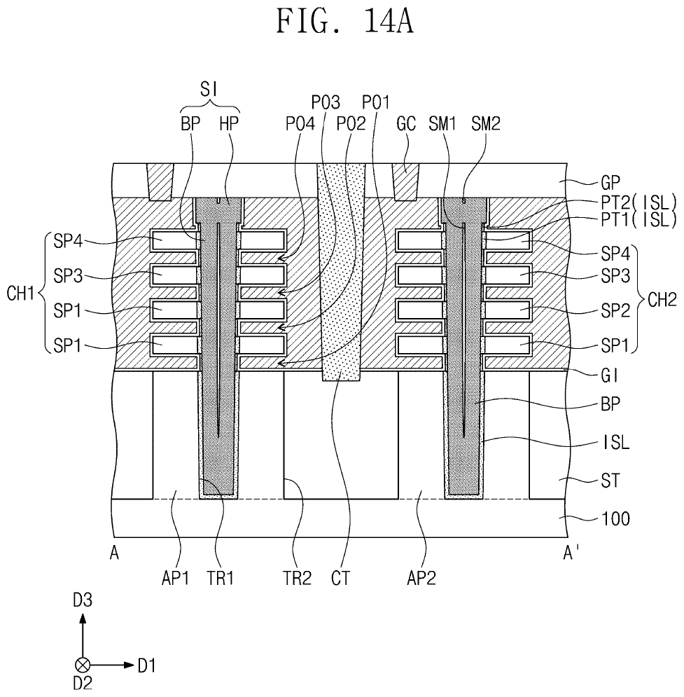

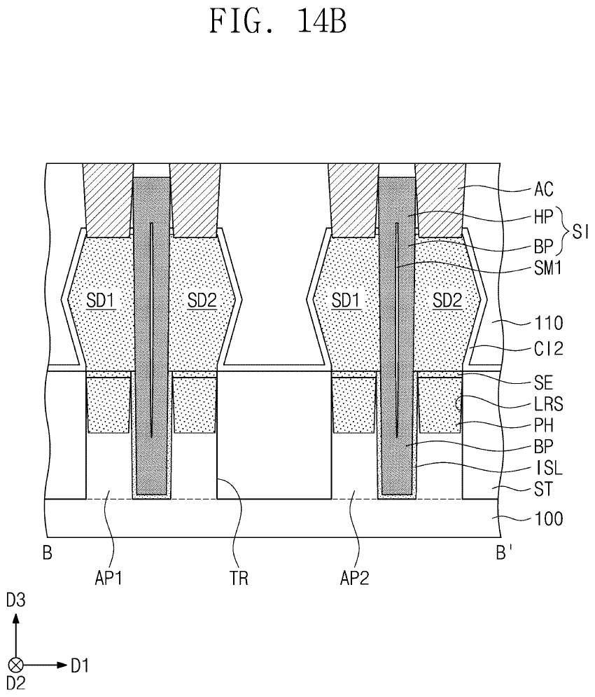

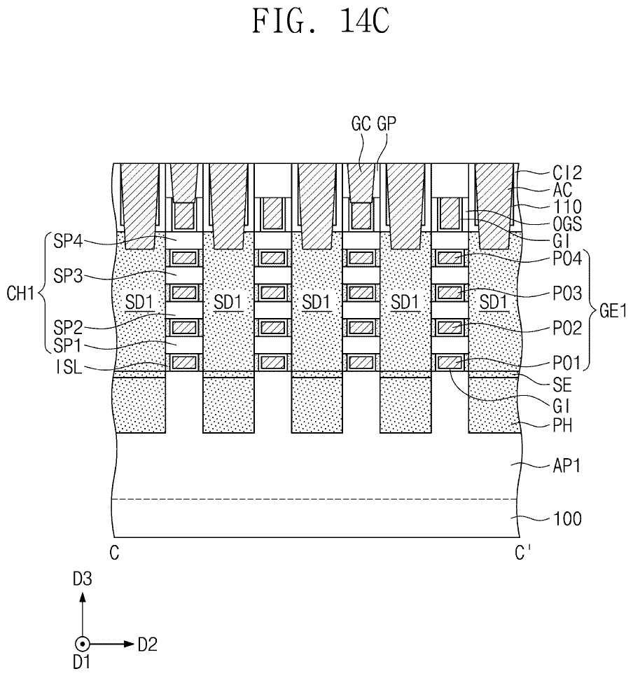

Referring to FIGS. 14A, 14B, and 14C, the second portion PT2 of the inner insulating pattern ISL may be formed on a side surface of the body portion BP, which is exposed by the first to fourth inner regions IRG1, IRG2, IRG3, and IRG4 and the outer region ORG. The formation of the second portion PT2 may include forming an insulating layer to cover the side surface of the body portion BP, which is exposed by the first to fourth inner regions IRG1, IRG2, IRG3, and IRG4 and the outer region ORG, and partially etching the insulating layer.

A thickness of the second portion PT2 may be smaller than a thickness of the first and third portions PT1 and PT3. Thus, a thickness of the inner insulating pattern ISL may not be uniform. As another example, the thickness of the second portion PT2 may be larger than the thickness of the first and third portions PT1 and PT3. The second portion PT2 may include the same material as the first and third portion PT1 and PT3. Since the second portion PT2 is formed after the formation of the first and third portions PT1 and PT3, the second portion PT2 may include a material that is different from the first and third portions PT1 and PT3.

In the inner region IRG and the outer region ORG, the gate insulating layer GI may be formed to have a constant thickness. The gate insulating layer GI may cover the first to fourth semiconductor patterns SP1, SP2, SP3, and SP4 of the first and second channel patterns CH1 and CH2, the separation pattern SI, and the device isolation pattern ST.

The first and second gate electrodes GE1 and GE2 may be formed on the gate insulating layer GI. The formation of the first and second gate electrodes GE1 and GE2 may include forming the first to fourth inner electrodes PO1, PO2, PO3, and PO4 between the first to fourth semiconductor patterns SP1, SP2, SP3, and SP4 and forming the outer electrode PO5 in the outer region ORG.

The gate capping patterns GP may be formed on the first and second gate electrodes GE1 and GE2. A planarization process may be performed on the gate capping patterns GP such that the top surfaces of the gate capping patterns GP is coplanar with the top surface of the first interlayer insulating layer 110.

Next, the cutting patterns CT may be formed to penetrate or extend in the first and second gate electrodes GE1 and GE2. The cutting patterns CT may be extended from the gate capping patterns GP to the device isolation pattern ST. The first and second gate electrodes GE1 and GE2 may be spaced apart from each other in the first direction D1 by the cutting patterns CT.

The active contacts AC may be formed in the first interlayer insulating layer 110. Each of the active contacts AC may penetrate or extend in the first interlayer insulating layer 110 and may be connected to at least one of the first and second source/drain patterns SD1 and SD2. The gate contacts GC may be formed in the gate capping patterns GP. The gate contacts GC may penetrate or extend in the gate capping patterns GP and may be connected to the first and second gate electrodes GE1 and GE2, respectively.

Referring back to FIGS. 2A, 2B, and 2C, the second interlayer insulating layer 120 may be formed on the first interlayer insulating layer 110. The upper vias UV may be formed in the second interlayer insulating layer 120. The upper vias UV may penetrate or extend in the second interlayer insulating layer 120 and may be connected to the active contacts AC and the gate contacts GC.

As another example, the substrate 100 may be inverted to expose the bottom surface of the substrate 100. A back-side active contact, which is connected to at least one of the first and second source/drain patterns SD1 and SD2, may be formed on the bottom surface of the substrate 100. The formation of the back-side active contact may include removing a portion of the substrate 100 to expose the sacrificial contact pattern PH and removing the exposed sacrificial contact pattern PH. The back-side active contact may be formed, in a self-aligned manner, using the sacrificial contact pattern PH, but the scope of this disclosure is not limited thereto.

After the formation of the back-side active contact, the power delivery network layer may be formed on the bottom surface of the substrate 100. The formation of the power delivery network layer may include forming a plurality of interconnection patterns and a plurality of via patterns.

Accordingly, based on fabrication processes such as those described with respect to FIGS. 4 to 14B, the inner insulating pattern ISL may be formed on a side surface of the separation pattern SI constituting the logic transistor. The width of the inner insulating pattern ISL may not be uniform. Since the separation pattern SI is spaced apart from the first and second channel patterns CH1 and CH2 by the inner insulating pattern ISL, it may be possible to prevent the performance of the semiconductor device from being deteriorated by a parasitic capacitance and fixed charges between the separation pattern SI and the first and second channel patterns CH1 and CH2. In addition, an overlapping length between the first and second channel patterns CH1 and CH2 and the gate electrodes GE1 and GE2 may be increased.

Accordingly, as described herein, an inner insulating pattern may be provided on a sidewall of a separation pattern. The inner insulating pattern may include a first portion between a body portion of the separation pattern and a channel pattern and a second portion between a gate electrode and the separation pattern. A width of the first portion may be larger than a width of the second portion. Thus, the separation pattern and the channel pattern may be spaced apart from each other, and this may prevent the performance of the semiconductor device from being deteriorated by parasitic capacitance and fixed charge issues, which may occur between the separation pattern and the channel pattern.

Accordingly, as described herein, a semiconductor device may include a separation pattern, which includes a body portion and a head portion on the body portion. A width of the head portion may be larger than a width of the body portion. The head portion may prevent an upper portion of the body portion from being exposed (e.g., may entirely cover a top of the body portion), and thus, it may be possible to prevent the body portion and the inner insulating pattern from being unintentionally removed. Accordingly, it may be possible to secure a sufficient distance between the gate electrodes, which are spaced apart from each other with the separation pattern interposed therebetween. As a result, the durability and electrical characteristics of the semiconductor device may be improved.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

While various examples have been particularly shown and described, it will be understood by one of ordinary skill in the art that variations in form and detail may be made therein without departing from the spirit and scope of this disclosure.

What is claimed is:

1. A semiconductor device, comprising:
an active pattern on a substrate;
a first channel pattern and a second channel pattern on the active pattern and spaced apart from one another;
a separation pattern between the first and second channel patterns, the separation pattern comprising a body portion and a head portion on the body portion,
a gate electrode on the first and second channel patterns; and
an inner insulating pattern on a side surface of the body portion,
wherein the inner insulating pattern comprises:
a first portion between the first channel pattern and the separation pattern and between the second channel pattern and the separation pattern; and
a second portion between the gate electrode and the separation pattern, wherein a width of the first portion is larger than a width of the second portion.

2. The semiconductor device of claim 1, wherein a ratio of the width of the first portion to the width of the second portion is in a range from 1.5 to 5.

3. The semiconductor device of claim 1, wherein the first portion and the second portion comprise different materials from one another.

4. The semiconductor device of claim 1, wherein a width of the head portion is larger than a width of the body portion,
wherein the head portion and the body portion comprise a same material, and
wherein the head portion and the body portion form a single body.

5. The semiconductor device of claim 1, wherein the body portion extends in the active pattern, and
wherein the inner insulating pattern extends in a space between the body portion and the active pattern.

6. The semiconductor device of claim 1, wherein each of the first and second channel patterns comprises a plurality of semiconductor patterns, and
wherein the head portion is spaced vertically apart from an uppermost one of the plurality of semiconductor patterns.

7. The semiconductor device of claim 6, wherein a top surface of the inner insulating pattern is located at a level higher than a top surface of the uppermost one of the plurality of semiconductor patterns.

8. The semiconductor device of claim 1, wherein each of the first and second channel patterns comprises a plurality of semiconductor patterns, and
wherein a portion of an uppermost one of the plurality of semiconductor patterns is in direct contact with the head portion.

9. The semiconductor device of claim 1, wherein the body portion comprises a first seam extending in a vertical direction, and
wherein the first seam is in contact with the head portion.

10. The semiconductor device of claim 9, wherein the head portion comprises a second seam in an upper portion of the head portion, the second seam disconnected from the first seam.

11. A semiconductor device, comprising:
an active pattern on a substrate;
a first channel pattern and a second channel pattern on the active pattern and spaced apart from one another in a first direction;
a separation pattern between the first and second channel patterns, the separation pattern comprising a body portion and a head portion on the body portion,
a gate electrode on the first and second channel patterns; and
an inner insulating pattern covering opposite side surfaces of the body portion,
wherein the head portion has a first width in the first direction,
wherein the body portion has a second width in the first direction,
wherein the inner insulating pattern comprises a first sidewall and a second sidewall, the first sidewall and the second sidewall facing the gate electrode,
wherein a distance between the first sidewall and the second sidewall in the first direction is a third width, and
wherein the third width is larger than the second width and is smaller than the first width.

12. The semiconductor device of claim 11, wherein each of the first and second channel patterns comprises a plurality of semiconductor patterns, and
wherein the head portion is located at a level higher than a top surface of an uppermost one of the plurality of semiconductor patterns.

13. The semiconductor device of claim 11, wherein the body portion extends in the active pattern, and
wherein the inner insulating pattern extends in a space between the body portion and the active pattern.

14. The semiconductor device of claim 11, wherein each of the first and second channel patterns comprises a plurality of semiconductor patterns, and
wherein the head portion is spaced vertically apart from an uppermost one of the plurality of semiconductor patterns.

15. The semiconductor device of claim 11, wherein the inner insulating pattern comprises:
a first portion between the first channel pattern and the separation pattern and between the second channel pattern and the separation pattern; and
a second portion between the gate electrode and the separation pattern,
wherein the first portion and the second portion comprise different materials from one another.

16. A semiconductor device, comprising:
a substrate including an active pattern;
a device isolation layer defining the active pattern;
a first channel pattern and a second channel pattern on the active pattern and spaced apart from one another in a first direction;
first and second source/drain patterns connected to the first and second channel patterns;
a separation pattern between the first and second channel patterns;
a gate electrode on the first and second channel patterns;
a gate insulating layer interposed between the gate electrode and each of the first and second channel patterns;
an inner insulating pattern on bottom and side surfaces of the separation pattern;
a gate spacer on a side surface of the gate electrode;
a gate capping pattern on a top surface of the gate electrode;
an interlayer insulating layer covering the first and second source/drain patterns and the gate capping pattern;
an active contact extending in the interlayer insulating layer and electrically connected to one of the first source/drain patterns;
a gate contact extending in the gate capping pattern and the interlayer insulating layer and electrically connected to the gate electrode; and
a first metal layer on the interlayer insulating layer, the first metal layer comprising a first interconnection line electrically connected to the active contact and the gate contact,
wherein the separation pattern comprises a body portion and a head portion on the body portion,
wherein the inner insulating pattern comprises:
a first portion between the first channel pattern and the separation pattern and between the second channel pattern and the separation pattern, and
a second portion between the gate electrode and the separation pattern, and
wherein a ratio of a width of the first portion to a width of the second portion is in a range from 1.5 to 5.

17. The semiconductor device of claim 16, wherein a width of the head portion is larger than a width of the body portion,
wherein the head portion and the body portion comprise a same material, and
wherein the head portion and the body portion form a single body.

18. The semiconductor device of claim 16, wherein the body portion extends in the active pattern, and
wherein the inner insulating pattern extends in a space between the body portion and the active pattern.

19. The semiconductor device of claim 16, wherein each of the first and second channel patterns comprises a plurality of semiconductor patterns, and
wherein the head portion is located at a level higher than a top surface of an uppermost one of the plurality of semiconductor patterns.

20. The semiconductor device of claim 16, wherein the body portion comprises a first seam extending in a vertical direction, and
wherein the first seam is in contact with the head portion.
